(19) United States
(12) Patent Application Publication
(10) Pub. No.: US 2018/0240915 A1
(43) Pub. Date: Aug. 23, 2018

(54) ADVANCED TECHNIQUES TO MANIPULATE THE C-V CHARACTERISTICS OF VARIABLE CAPACITORS

(71) Applicant: QUALCOMM Incorporated, San Diego, CA (US)

(72) Inventors: Fabio Alessio MARINO, San Marcos, CA (US); Paolo MENEGOLI, San Jose, CA (US); Narasimhulu KANIKE, San Diego, CA (US); Francesco CAROBOLANTE, San Diego, CA (US)

(21) Appl. No.: 15/438,400

(22) Filed: Feb. 21, 2017

(51) Int. Cl. H01L 29/93; H01L 27/08; H01L 27/12

(52) U.S. Cl. CPC H01L 29/93; H01L 27/1203; H01L 27/0808

(57) ABSTRACT

Certain aspects of the present disclosure generally relate to techniques for adjusting or setting a capacitance-versus-voltage (C-V) characteristic of a variable capacitor. For example, certain aspects of the present disclosure provide a capacitor device. The capacitor device generally includes a first variable capacitor and a second variable capacitor, each comprising a first terminal and a second terminal. In certain aspects, the second terminal of the second variable capacitor is coupled to the first terminal of the first variable capacitor, and the first terminal of the first variable capacitor is coupled to at least one biasing voltage node. In some cases, a decoupling capacitor may be coupled to the first terminal of the first variable capacitor.

### TECHNICAL FIELD

Certain aspects of the present disclosure generally relate to electronic circuits and, more particularly, to variable semiconductor capacitors.

### BACKGROUND

Semiconductor capacitors are fundamental components for integrated circuits. A variable capacitor is a capacitor whose capacitance may be intentionally and repeatedly changed under the influence of a bias voltage. A variable capacitor, which may be referred to as a varactor, is often used in inductor-capacitor (LC) circuits to set the resonance frequency of an oscillator, or as a variable reactance, e.g., for impedance matching in antenna tuners.

A voltage-controlled oscillator (VCO) is an example circuit that may use a varactor in which the thickness of a depletion region formed in a p-n junction diode is varied by changing a bias voltage to alter the junction capacitance. Any junction diode exhibits this effect (including p-n junctions in transistors), but devices used as variable capacitance diodes are designed with a large junction area and a doping profile specifically chosen to improve the device performance, such as quality factor and tuning range.

### SUMMARY

Certain aspects of the present disclosure generally relate to techniques for adjusting or setting a capacitance-versus-voltage (C-V) characteristic of a variable capacitor (e.g. to obtain a linear, or exponential, or polynomial C-V characteristic).

Certain aspects of the present disclosure provide a capacitor device. The capacitor device generally includes a first variable capacitor and a second variable capacitor, each comprising a first terminal and a second terminal, wherein the second terminal of the second variable capacitor is coupled to the first terminal of the first variable capacitor, and the first terminal of the first variable capacitor is coupled to at least one biasing voltage node, and a decoupling capacitor coupled to the first terminal of the first variable capacitor.

Certain aspects of the present disclosure provide a capacitor device. The capacitor device generally includes a first variable capacitor and a second variable capacitor, each comprising a first terminal and a second terminal, wherein the first and second terminals of the first variable capacitor are coupled to the first and second terminals of the second variable capacitor, respectively, and the first terminal of the first variable capacitor and the second variable capacitor are coupled to a first biasing voltage node.

Certain aspects of the present disclosure provide a capacitor device. The capacitor device generally includes a first transcap (TC) device and a second TC device, each comprising a first capacitor (C1) terminal, a second capacitor (C2) terminal, and a control terminal, wherein the control terminal is configured such that a capacitance between the C1 terminal and the C2 terminal is adjusted by varying a control voltage applied to the control terminal (and/or to the C2 terminal); wherein the C2 terminal of the first TC device is coupled to the C2 terminal of the second TC device; wherein at least one of the first TC device or the second TC device comprises a non-insulative region coupled to at least one of the C1 terminal, the C2 terminal, or the control terminal, of the at least one of the first TC device or the second TC device; and wherein the non-insulative region has a shape other than a quadrilateral with four right angles.

Certain aspects of the present disclosure provide a capacitor device. The capacitor device generally includes a first transcap (TC) device and a second TC device, each comprising a first capacitor terminal, a second capacitor terminal, and a control terminal, wherein the control terminal is configured such that a capacitance between the first capacitor terminal and the second capacitor terminal is adjusted by varying a control voltage applied to the control terminal (and/or to the C2 terminal), the first capacitor terminal of the first TC device is coupled to at least one biasing voltage node, and the second capacitor terminal of the second TC device is coupled to the at least one biasing voltage node, and a decoupling capacitor coupled to the first capacitor terminal of the first TC device.

Certain aspects of the present disclosure provide a method for adjusting a C-V characteristic of a capacitor device. The method generally includes generating at least one biasing voltage and adjusting a C-V characteristic of the capacitor device by applying the at least one biasing voltage to a first capacitor terminal of a first TC device and a second capacitor terminal of a second TC device.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a cross-sectional view of an example semiconductor variable capacitor.

FIG. 2 illustrates a cross-sectional view of an example differential semiconductor variable capacitor.

FIG. 3A is a schematic diagram of an example semiconductor variable capacitor implemented by connecting multiple differential variable capacitors in series, in accordance with certain aspects of the present disclosure.

FIG. 3B is a schematic diagram of an example semiconductor variable capacitor implemented by connecting multiple variable capacitors in series, in accordance with certain aspects of the present disclosure

FIG. 4 is a graph of an example capacitance-versus-voltage (C-V) characteristic of the semiconductor variable capacitor of FIG. 3A, in accordance with certain aspects of the present disclosure.

FIG. 5A is a schematic diagram of an example semiconductor variable capacitor implemented by connecting multiple differential variable capacitors in parallel, in accordance with certain aspects of the present disclosure.

FIG. 5B is a schematic diagram of an example semiconductor variable capacitor implemented by connecting multiple variable capacitors in parallel, in accordance with certain aspects of the present disclosure.

FIG. 6 is a graph of an example C-V characteristic of the semiconductor variable capacitor of FIG. 5A, in accordance with certain aspects of the present disclosure.

FIG. 7 is a schematic diagram of an example semiconductor variable capacitor implemented by connecting multiple differential variable capacitors in parallel and biased using different biasing voltages, in accordance with certain aspects of the present disclosure.

FIG. 8 is a schematic diagram of an example semiconductor variable capacitor implemented by connecting multiple differential variable capacitors in parallel and biased using a common bias voltage, in accordance with certain aspects of the present disclosure.

FIG. 9 is a schematic diagram of an example semiconductor variable capacitor implemented by connecting multiple differential variable capacitors in parallel having different doping structures, in accordance with certain aspects of the present disclosure.

FIG. 10 illustrates a top-down perspective of an example structure of a semiconductor variable capacitor, in accordance with certain aspects of the present disclosure.

FIG. 11 illustrates top-down perspectives of example structures of semiconductor variable capacitors using a trapezoid shaped polysilicon region, in accordance with certain aspects of the present disclosure.

FIG. 12 illustrates top-down perspectives of example structures of semiconductor variable capacitors using different shaped polysilicon regions, in accordance with certain aspects of the present disclosure.

FIG. 13 is a flow diagram of example operations for adjusting a C-V characteristic of a capacitor device, in accordance with certain aspects of the present disclosure.

### DETAILED DESCRIPTION

Certain aspects of the present disclosure are generally directed to a semiconductor variable capacitor structure, also referred to as a transcap (TC) device, suitable for integrated circuits. A TC device may have at least three terminals, where the capacitance between two main terminals of the device (C1 and C2) can be varied by changing a voltage applied between a control terminal CTRL and one of the other two main terminals (e.g., C2). Certain aspects of the present disclosure are generally directed to adjusting a capacitance-versus-voltage (C-V) characteristic of a variable capacitor which may be implemented using TC devices.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

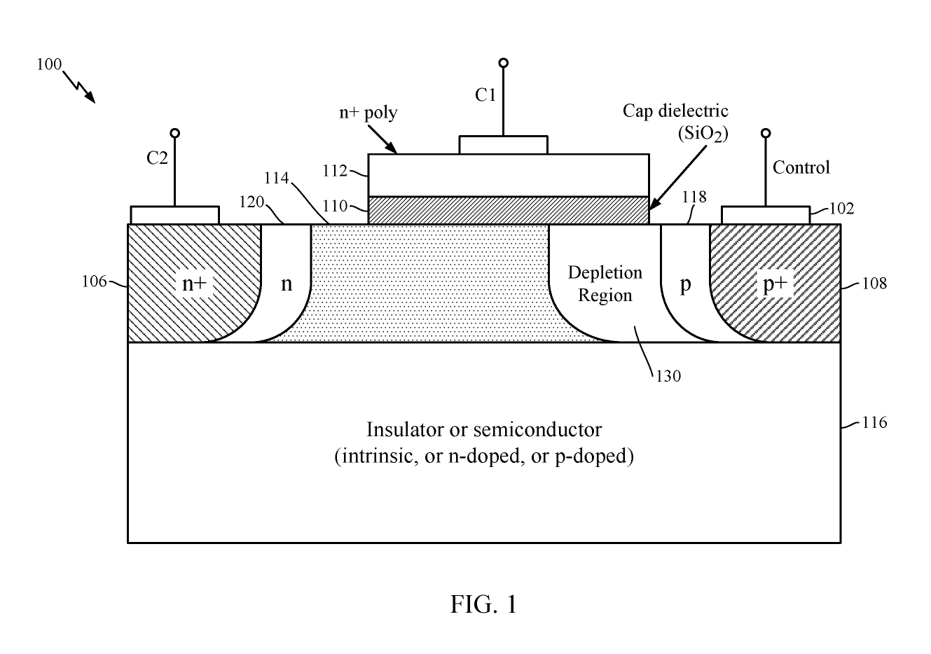

FIG. 1 illustrates a cross-sectional view of an example structure of a TC device 100. Certain implementations of a TC device use an oxide layer 110, which may be similar to oxide layers used to fabricate metal-oxide semiconductor (MOS) devices (e.g., thin or thick gate oxide). The oxide layer 110 may isolate the C1 and C2 terminals, and thus, in effect act as a dielectric for the TC device 100. A non-insulative region 106 (e.g., n+ implantation region) and a non-insulative region 108 (e.g., p+ implantation region) may be formed on the two sides of the TC device 100 in order to create p-n junctions. As used herein, a non-insulative region generally refers to a region that may be conductive or semiconductive. A bias voltage may be applied between the control terminal 102 and the C2 terminal in order to modulate the capacitance between terminals C1 and C2. For example, by applying a bias voltage to the control terminal 102, a depletion region 130 may be formed at the p-n junction between the non-insulative region 108 (e.g., control region) and the semiconductor region 114. Based on the bias voltage, this depletion region 130 may widen under the oxide layer 110, reducing the area of the equivalent electrode formed by the semiconductor region 114, and with it, the effective capacitance area and capacitance value of the TC device 100.

The work-function of a non-insulative region 112 above the oxide layer 110 may be chosen to improve the device performance. For example, an n-doped polysilicon material may be used (instead of p-doped), even if the semiconductor region 114 underneath the oxide layer 110 is doped with n-type impurities. In some aspects, a metallic material (also doped if desired) may be used for the non-insulative region 112 with an opportune work-function or a multi-layer stack of different metallic materials so as to obtain the desired work-function. In certain aspects, non-insulative region 112 may be divided into two sub-regions, one n-doped and one p-doped, or a different metallic material may be used for each sub-region.

In some cases, the semiconductor region 114 may be disposed above an insulator or semiconductor region 116. The type of material for the semiconductor region 116 may be chosen in order to improve the TC device 100 performance. For example, the semiconductor region 116 may be an insulator, a semi-insulator, or an intrinsic/near-intrinsic semiconductor in order to decrease the parasitic capacitances associated with the substrate (not shown). In some cases, the semiconductor region 116 can be made of n-doped or p-doped semiconductor with an appropriate doping profile in order to increase the TC device quality factor and/or the control on the depletion region 130 that may be formed between the non-insulative region 108 and the semiconductor region 114 when applying a bias voltage to the control terminal 102. The semiconductor region 116 can also be formed by multiple semiconductor layers or regions doped in different ways (n, p, or intrinsic). Furthermore, the semiconductor region 116 can include semiconductors, insulating layers, and/or substrates or can be formed above semiconductors, insulating layers, and/or substrates.

To better understand the working principle of the TC device 100, it may be assumed that the control terminal 102 is biased with a negative voltage with respect to the C2 terminal, for example. The width of the depletion region 130 in the semiconductor region 114 may be controlled by applying a control voltage to the control terminal 102. The capacitance between the C1 and C2 terminals may depend on the dimensions of the depletion region 130 in the semiconductor region 114, and thus, can be controlled by applying the control voltage to the control terminal 102. Furthermore, the variation of the bias voltage applied to the control terminal 102 may not alter the DC voltage between the C1 and C2 terminals, allowing for improved control of the device characteristics.

In some cases, it may be preferable to have the non-insulative region 106 and/or non-insulative region 108 a distance away from the oxide layer 110 in order to reduce the parasitic capacitance associated with the non-insulative region 108 and improve the isolation of the non-insulative region 106 for high control voltages. For example, the non-insulative region 106 can be partially overlapped with the oxide layer 110, or the non-insulative region 106 can be formed at a distance from the edge of the oxide layer 110 so as to increase the device tuning range and linearity. In the latter case, the voltage-withstanding capability of the device is increased since a portion of a radio frequency (RF) signal, that may be applied to the C1 and C2 terminals, drops between the oxide edge and the non-insulative region 106 instead of being applied entirely across the oxide layer 110. The non-insulative region 108 can be partially overlapped with the oxide layer 110, or the non-insulative region 108 can be spaced apart so as to reduce the parasitic capacitance between the C1 terminal and the control terminal 102.

A p-doped region 118 can be optionally used to increase the breakdown voltage of the p-n junction between non-insulative region 108 and semiconductor region 114, decreasing, at the same time, the parasitic capacitance between the C1 terminal and the control terminal 102. Similarly, an optional n-doped region 120 can be added between the non-insulative region 106 and semiconductor region 114 in order to regulate the doping concentration between the oxide layer 110 and the non-insulative region 106.

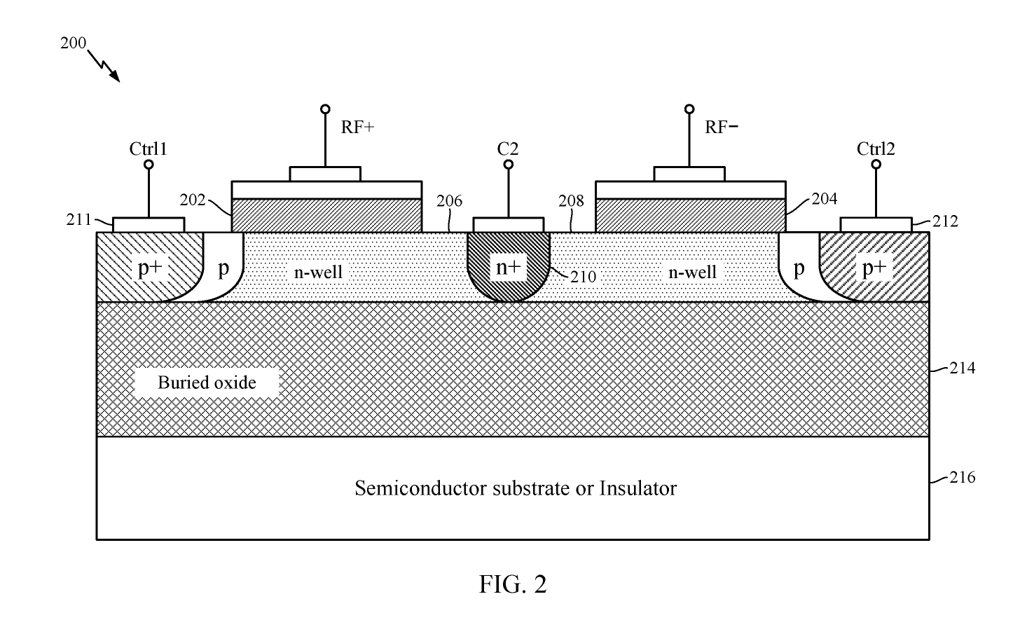

FIG. 2 illustrates an example differential TC device 200 in cross section. The differential TC device 200 can be obtained by disposing two of the TC devices 100 back-to-back. In this example, RF+ and RF− terminals (e.g., corresponding to the C1 terminal in FIG. 1) correspond to the positive and negative nodes of a differential RF port for a differential RF signal. The RF+ terminal may be disposed on an oxide layer 202, and the RF− terminal may be disposed on an oxide layer 204. N-well regions 206 and 208 may be coupled to a C2 terminal via a non-insulative region 210 (e.g., n+), as illustrated. A bias voltage may be applied to the control terminals 211 and 212 (or to the C2 terminal with respect to the other terminals of the device) to adjust a depletion region of the n-well regions 206 and 208, respectively, thereby adjusting the capacitance between respective RF+ and RF− terminals and the C2 terminal. In some aspects, a buried oxide layer 214 may be positioned below the n-well regions 206 and 208 and above a semiconductor substrate or insulator 216, as illustrated.

Certain aspects of the present disclosure are generally directed to techniques for adjusting a C-V characteristic of a TC device. Generally, modifying the C-V characteristic of a semiconductor variable capacitor may be costly as the C-V characteristic may be modified by adjusting the manufacturing processes of the semiconductor variable capacitor. Furthermore, adjusting the manufacturing processes of a semiconductor variable capacitor may pose some performance trade-offs which may not be desired in certain high performance applications. For example, the C-V characteristic may be adjusted by thinning the poly oxide of the semiconductor variable capacitor or increasing the poly length of the semiconductor variable capacitor. These process modifications may adjust the C-V characteristic of the semiconductor variable capacitor and may also increase the tuning range, but may decrease the quality factor of the semiconductor variable capacitor. Moreover, increasing the poly oxide thickness may improve the quality factor and the linearity, but may degrade the tuning range of the semiconductor variable capacitor.

Certain aspects of the present disclosure are directed to techniques for manipulating the C-V characteristic of a variable capacitor, which may entail connecting multiple variable capacitors having different properties. By connecting multiple variable capacitor having different properties, the combined C-V characteristic of the resulting variable capacitor is the weighted combination of the C-V characteristic of each individual variable capacitor. Multiple techniques are provided herein for adjusting the C-V characteristic of a variable capacitor, which may be used individually, or in combination, to obtain a desired C-V characteristic.

In certain aspects, multiple variable capacitors may be connected, each having one or more different process parameters, such as well-doping profiles, oxide thickness, and/or “gate” work-functions (e.g. n-poly or p-poly). In some cases, multiple variable capacitors may be connected, each having different geometry parameters, such as polysilicon length, polysilicon width, or drift length. In certain aspects, multiple variable capacitors may be connected, each with different bias conditions. In certain aspects, a p-type variable capacitor and an n-type variable capacitor may be connected to obtain a desired C-V characteristic. In certain aspects, one or more variable capacitors may be connected with one or more metal-insulator-metal (MIM) capacitors. In some cases, the layout shape used in manufacturing the variable capacitor, such as trapezoidal, circular, or squared 3D shape, may be used to change the electric field distribution inside the variable capacitor, and thus, obtain a desired C-V characteristic.

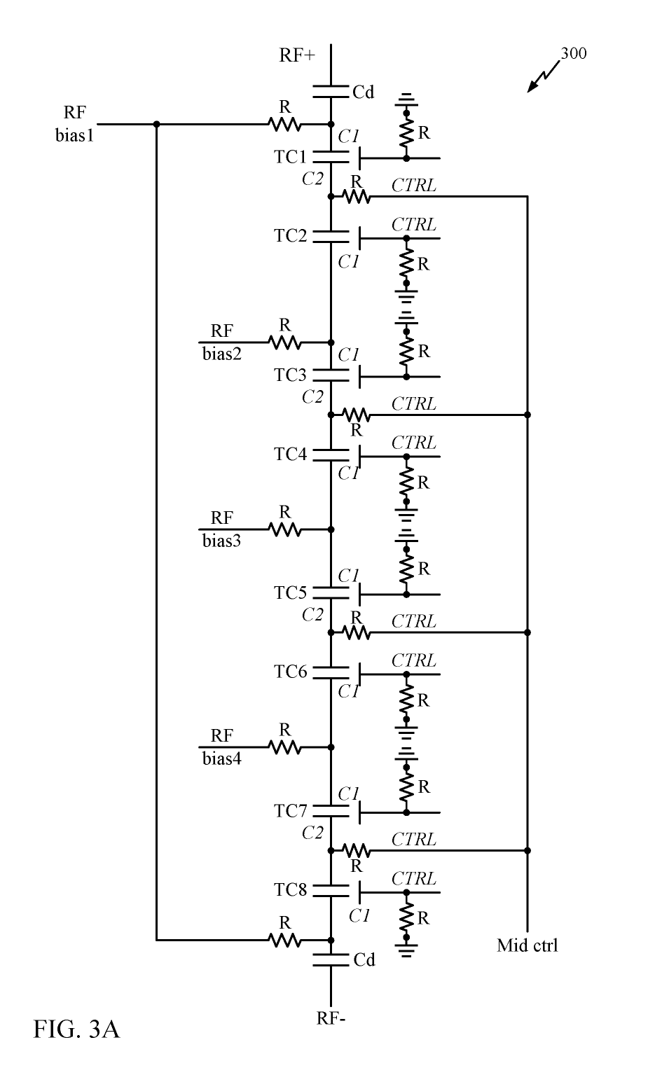

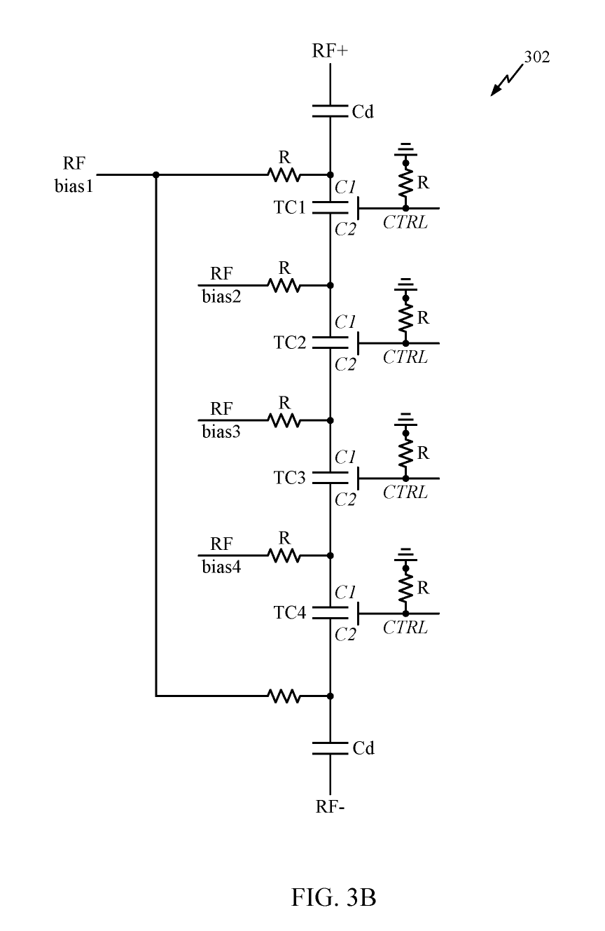

FIG. 3A is a schematic diagram of an example semiconductor variable capacitor 300 implemented by connecting multiple differential TC devices in series, in accordance with certain aspects of the present disclosure. For example, the semiconductor variable capacitor 300 may include a first TC device (TC1) having a first capacitor (C1) terminal, a second capacitor (C2) terminal, and a control (CTRL) terminal. As presented above, the CTRL terminal may be configured such that a capacitance between the C1 terminal and the C2 terminal is adjusted by varying a voltage applied to the CTRL terminal. In this case, TC1 is connected to a second TC device (TC2). That is, a differential TC device is implemented by connecting TC1 and TC2 as described with respect to FIG. 2. In this case, TC3 and TC4 implement a second differential TC device, TC5 and TC6 implement a third differential TC device, and TC7 and TC8 implement a fourth differential TC device.

In certain aspects, the C1 terminals of the TC devices of the semiconductor variable capacitor 300 may be biased to obtain a desired C-V characteristic. For example, a first bias voltage (RF bias 1) may be applied to the C1 terminals of TC1 and TC8, a second bias voltage (RF bias 2) may be applied to the C1 terminal of TC3, a third bias voltage (RF bias 3) may be applied to the C1 terminal of TC5, and a fourth bias voltage (RF bias 4) may be applied to the C1 terminal of TC7. Thus, the C-V characteristic of the semiconductor variable capacitor 300 can be adjusted by varying the bias voltages RF bias 1, RF bias 2, RF bias 3, and RF bias 4. In certain aspects, the different bias voltages RF bias 1, RF bias 2, RF bias 3, and RF bias 4 may be generated using a ladder of resistors (e.g., a voltage divider circuit). As illustrated, the bias voltages RF bias 1, RF bias 2, RF bias 3, and RF bias 4 may be applied through a biasing impedance (R), which may be a large impedance component on the order of 100 kΩ. In certain aspects, in order to apply a biasing voltage to the C1 terminals of TC1 and TC8, a decoupling capacitor Cd may be coupled to the C1 terminals of the first and last TC devices (e.g., TC1 and TC8) in the series. In some cases, the decoupling capacitors Cd may be large enough to reduce their impact on the tuning range of the semiconductor variable capacitor 300. However, this may not be the case where the decoupling capacitors Cd are used to reduce the voltage drop across the TC devices. In certain aspects, the bias voltages of the first and last TC devices (e.g., TC1 and TC8) may be different from each other.

FIG. 3B is a schematic diagram of an example semiconductor variable capacitor 302 implemented by connecting multiple TC devices in series, in accordance with certain aspects of the present disclosure. For example, instead of using two TC devices (e.g., TC1 and TC2 of FIG. 3A) connected back-to-back to implement a differential series, a single TC device (e.g., TC1 of FIG. 3B) may be used. That is, the semiconductor variable capacitor 302 includes a first TC device (TC1), a second TC device (TC2), a third TC device (TC3), and a fourth TC device (TC4), each having a C1 terminal and a C2 terminal. The C1 and C2 terminals of TC1, TC2, TC3, and TC4 may be biased using bias voltages (RF bias 1-4) as illustrated to adjust the total C-V characteristic of the semiconductor variable capacitor 302. In certain aspects, one or more decoupling capacitor may be inserted between the different TC devices of FIGS. 3A and 3B.

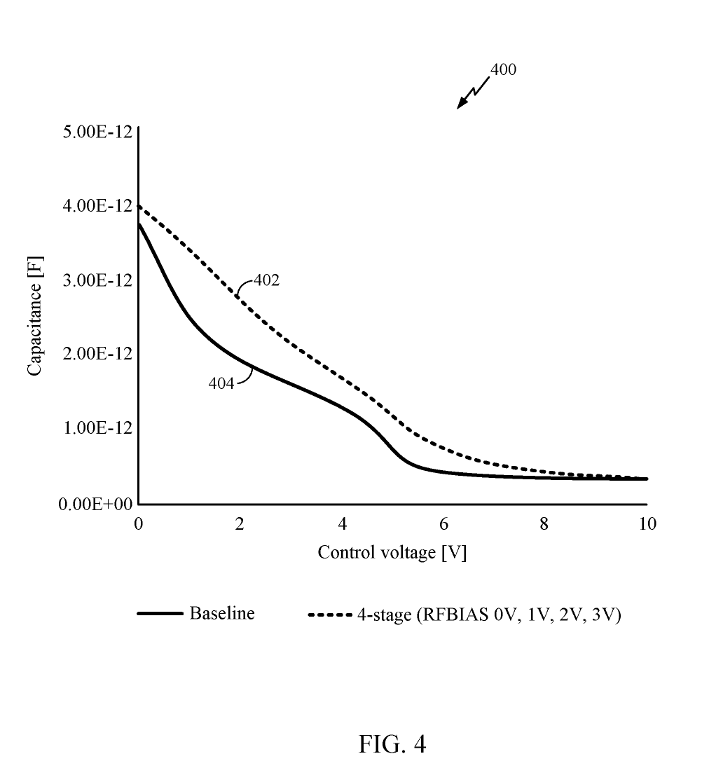

FIG. 4 is a graph 400 of an example C-V characteristic of the semiconductor variable capacitor 300 of FIG. 3A, in accordance with certain aspects of the present disclosure. The dashed line 402 represents the C-V characteristic of the semiconductor variable capacitor 300 with RF bias 1 equal to 0 volts, RF bias 2 equal to 1 volt, RF bias 3 equal to 2 volts, and RF bias 4 equal to 3 volts. As illustrated, the C-V characteristic is different than the baseline 404, which represents the C-V characteristic of the semiconductor variable capacitor 300 without the bias voltages RF bias 1, RF bias 2, RF bias 3, and RF bias 4.

Returning to FIG. 3A, in certain aspects, the C-V characteristic of the semiconductor variable capacitor 300 can be adjusted by varying another bias (labeled “mid ctrl”) voltage applied to the C2 terminals of the TC devices, as illustrated. In FIG. 3A, the same mid ctrl voltage is applied to all the TC devices. However, in certain aspects, separate bias voltages may be applied to the C2 terminals of each of at least one of TC1, TC3, TC5, and TC7, allowing more flexibility in adjusting the C-V characteristic of the semiconductor variable capacitor 300. In the case where the bias voltages RF bias 1, RF bias 2, RF bias 3, and RF bias 4 are not applied to the semiconductor variable capacitor 300 (e.g., only mid ctrl is used to adjust the C-V characteristic), the semiconductor variable capacitor 300 may not include the decoupling capacitors Cd.

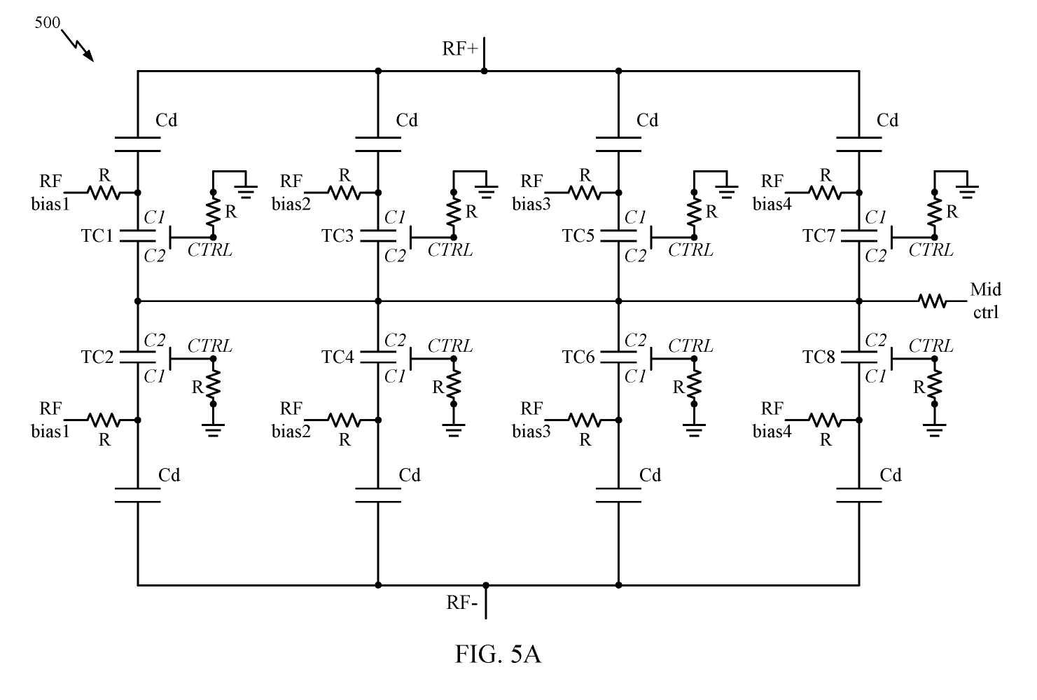

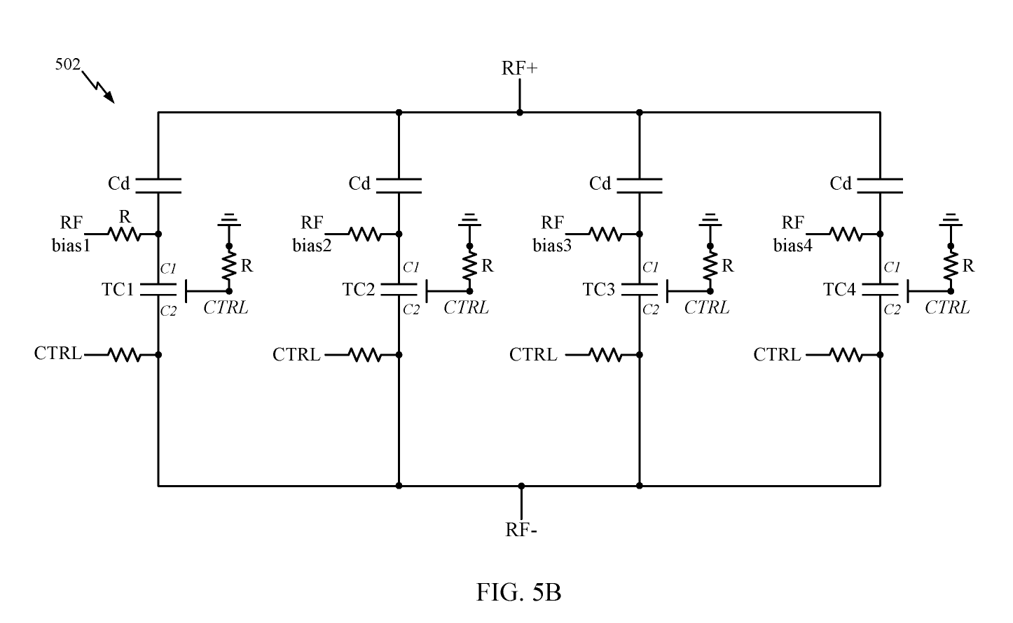

FIG. 5A is a schematic diagram of an example semiconductor variable capacitor 500 implemented by connecting multiple differential TC devices in parallel, in accordance with certain aspects of the present disclosure. In this case, each of the differential TC devices may be biased with a different bias voltage. For example, RF bias 1 may be applied to the C1 terminals of TC1 and TC2, RF bias 2 may be applied to the C1 terminals of TC3 and TC4, RF bias 3 may be applied to the C1 terminals of TC5 and TC6, and RF bias 4 may be applied to the C1 terminals of TC7 and TC8, as illustrated. In this case, each of the differential TC devices may be coupled to a decoupling capacitor Cd, electrically decoupling the bias voltages from the RF+ and RF− nodes. In certain aspects, the different bias voltages RF bias 1, RF bias 2, RF bias 3, and RF bias 4 may be generated using a ladder of resistors (e.g., a voltage divider circuit).

FIG. 5B is a schematic diagram of an example semiconductor variable capacitor 502 implemented by connecting multiple TC devices in parallel, in accordance with certain aspects of the present disclosure. For example, instead of using two TC devices (e.g., TC1 and TC2 of FIG. 3A) connected back-to-back to implement a differential series, a single TC device (e.g., TC1 of FIG. 3B) may be used in each branch. Thus, the semiconductor variable capacitor 502 includes a first TC device (TC1), a second TC device (TC2), a third TC device (TC3), and a fourth TC device (TC4), each having a C1 terminal and a C2 terminal. At least one of the C1 or C2 terminals of TC1, TC2, TC3, and TC4 may be biased using bias voltages (RF bias 1-4) as illustrated to adjust the total C-V characteristic of the semiconductor variable capacitor 502. In certain aspects, the C2 terminal of the TC1, TC2, TC3, and TC4 may be coupled to a CTRL terminal. Optionally, each of the C2 terminals of TC1, TC2, TC3, and TC4 may be coupled to a decoupling capacitor.

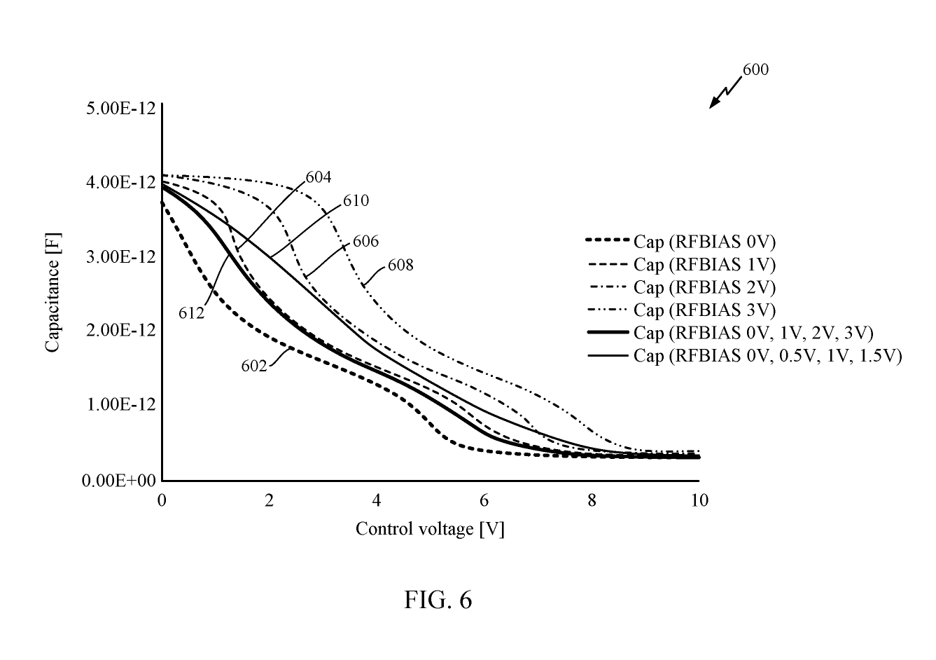

FIG. 6 is a graph 600 of an example C-V characteristic of the semiconductor variable capacitor 500, in accordance with certain aspects of the present disclosure. Lines 602, 604, 606, and 608 illustrate a C-V characteristic of a differential TC device biased at 0 volts, 1 volt, 2 volts, and 3 volts, respectively. The line 610 illustrates a combined C-V characteristic of the semiconductor variable capacitor 500 having multiple TC devices connected in parallel and respectively biased at 0 volts, 1 volt, 2 volts, and 3 volts as described with respect to FIG. 5A. Line 612 illustrates a combined C-V characteristic of the semiconductor variable capacitor 500 having multiple differential TC devices respectively biased at 0 volts, 0.5 volts, 1 volt, and 1.5 volts. As can be seen in the graph 600, the application of different RF biases in each branch (e.g., differential TC device) skews the C-V characteristics of the branches so as to impact the total C-V capacitance between the RF+ and RF− nodes and therefore the total C-V characteristic of the semiconductor variable capacitor 500.

While the examples provided herein have used four TC devices to facilitate understanding, the techniques presented herein can be implemented with two or more TC devices. In certain aspects, the C2 terminals of the differential TC devices can be shorted together directly or indirectly (e.g., through a high impedances), or the C2 terminals can be driven with a voltage offset. For example, as illustrated in FIG. 5A, the C2 terminals of TC1, TC3, TC5, and TC7 may be biased by a mid ctrl voltage.

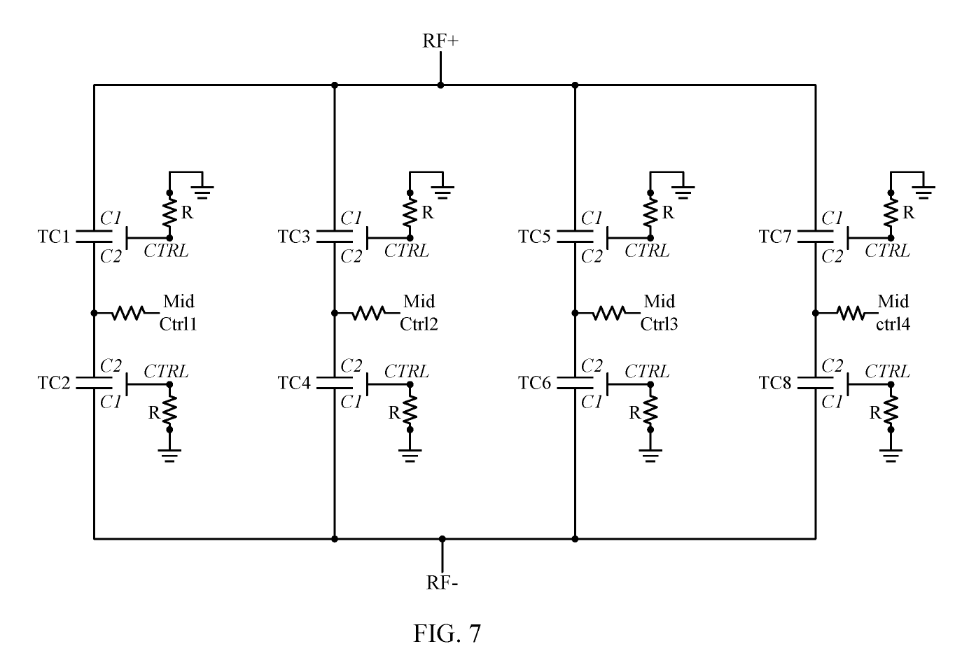

FIG. 7 is a schematic diagram of an example semiconductor variable capacitor 700 implemented by connecting multiple differential TC devices in parallel and biased using different mid ctrl voltages, in accordance with certain aspects of the present disclosure. For example, the C2 terminals of each of the differential TC devices may be biased using a different mid ctrl voltage, allowing greater flexibility in adjusting the C-V characteristic of the semiconductor variable capacitor 700. In some cases, the mid ctrl2 voltage may be generated by adding a voltage offset to the mid ctrl 1 voltage, the mid ctrl 3 voltage may be generated by adding a voltage offset to the mid ctrl 2 voltage, and so on. In some cases, some of the differential TC devices may be biased using the same mid ctrl voltage, while others may be biased using different mid ctrl voltages.

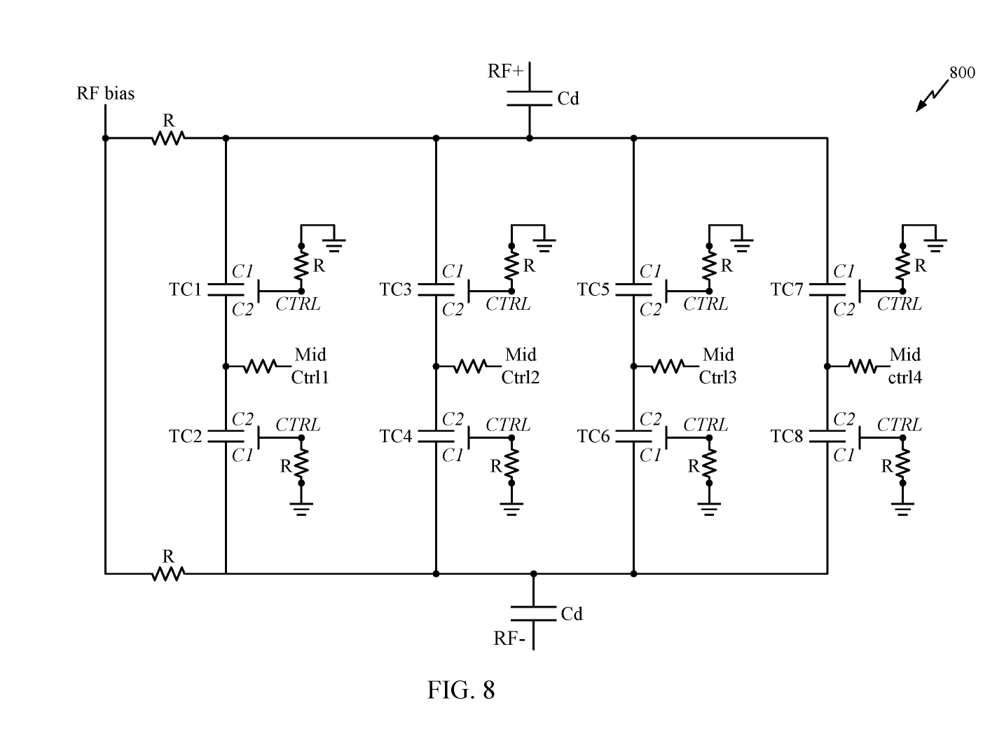

FIG. 8 is a schematic diagram of an example semiconductor variable capacitor 800 implemented by connecting multiple differential TC devices in parallel and biased using a common bias voltage, in accordance with certain aspects of the present disclosure. For example, a bias voltage (RF bias) may be applied to the C1 terminals of the differential TC devices. In this case, by applying a common bias voltage to the TC devices, a common decoupling capacitor Cd may be used. In certain aspects, each branch of the semiconductor variable capacitor 800 may be implemented using a single TC device as opposed to a differential TC device implemented by connecting multiple TC devices.

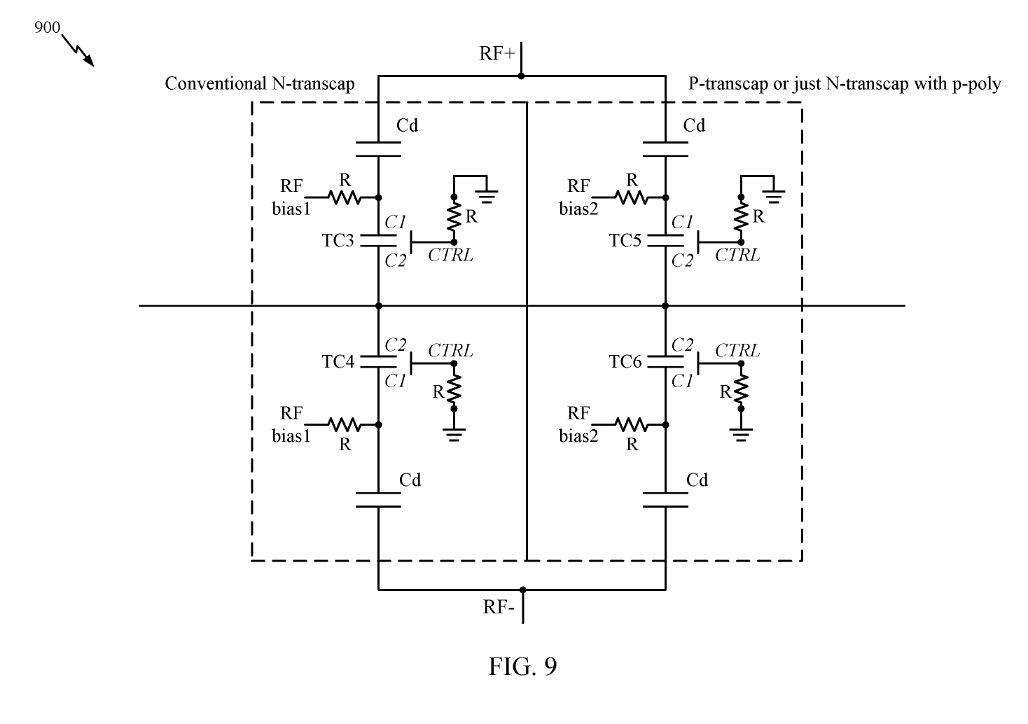

FIG. 9 is a schematic diagram of an example semiconductor variable capacitor 900 implemented by connecting multiple differential TC devices in parallel having different doping structures, in accordance with certain aspects of the present disclosure. That is, the C-V characteristic of the semiconductor variable capacitor 900 may be set using different doping structures for each of the differential TC devices. For example, the differential TC device implemented using TC3 and TC4 may be a n-type TC device as illustrated in FIG. 2. However, the differential TC device implemented using TC5 and TC6 may be a p-type TC device implemented similar to the differential TC device of FIG. 2, but by replacing the n-doped regions with p-doped regions, or vice-versa. In other cases, the differential TC device implemented using TC5 and TC6 may be an n-type TC device, but with a different work-function for the RF+ and RF− terminals with respect to TC3 and TC4 (e.g. p-poly or a different metal).

In the aspects described herein, the width (W) of the TC components connected in parallel (e.g., as shown in FIGS. 5A and 5B) and/or in series (e.g., as shown in FIGS. 3A and 3B) can be used to weight their contributions to the total C-V characteristic of the semiconductor variable capacitor. For example, multiple TC devices may be connected as described herein, each TC device having a different width and/or biased with a different bias voltage as described with respect to FIGS. 3A, 3B, 5A, 5B, and 7-9.

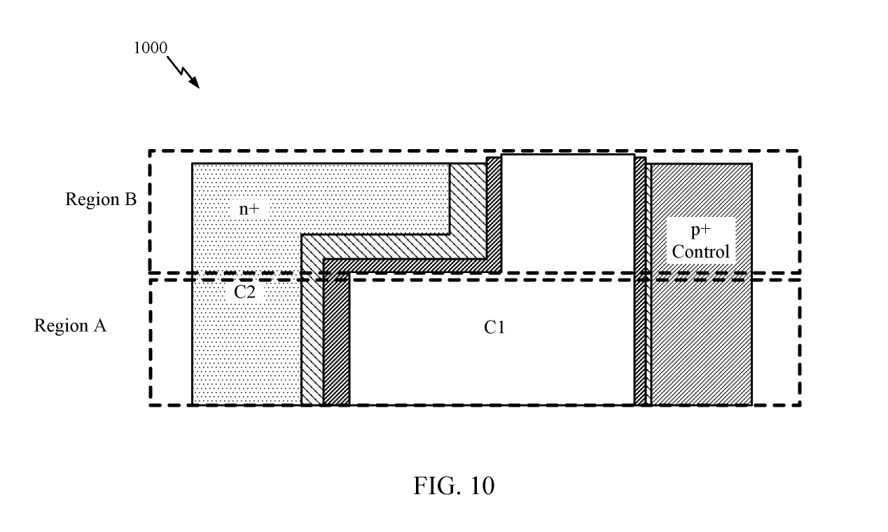

FIG. 10 illustrates a top-down perspective of an example structure of a semiconductor variable capacitor 1000, in accordance with certain aspects of the present disclosure. In this case, the C-V characteristic of a TC device may be manipulated by connecting in parallel multiple TC devices with different poly lengths. Different poly lengths for parallel TC devices can be obtained at the device level by using a structure as illustrated in FIG. 8. For example, region A of the semiconductor variable capacitor 1000 represents a first TC device with a certain poly-length, and region B represents a second TC device with a smaller poly-length, where the second TC device can be considered as being connected in parallel with the first TC device.

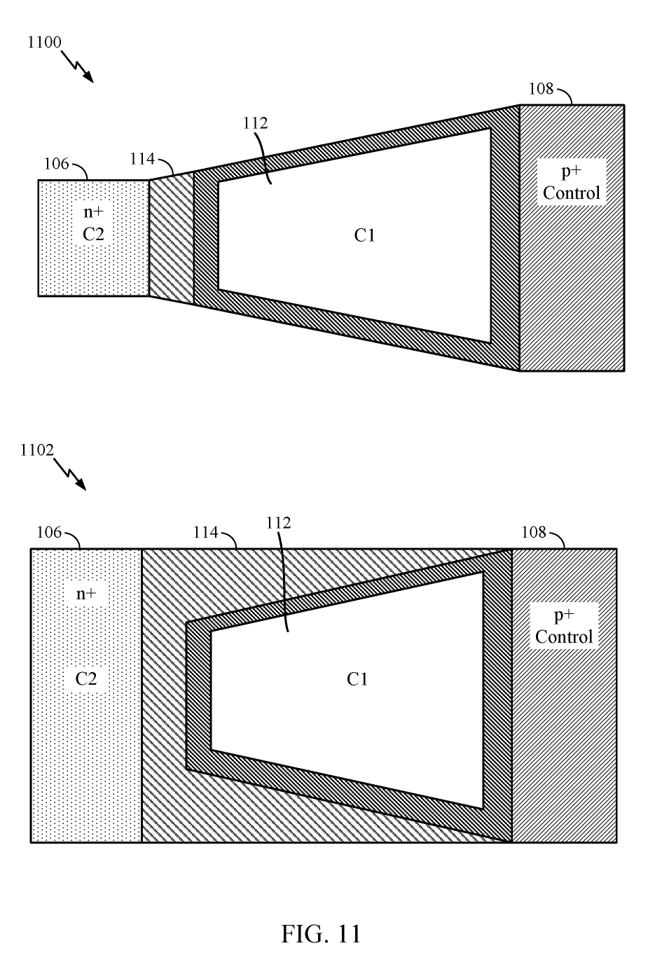

FIG. 11 illustrates top-down perspectives of example structures of semiconductor variable capacitors 1100 and 1102 using a trapezoid-shaped polysilicon region, in accordance with certain aspects of the present disclosure. For example, the non-insulative region for the C1 terminal of the semiconductor variable capacitor 1100 may be trapezoid-shaped when viewed from the top. Due to the asymmetry between the non-insulative region for the C2 terminal and control region, the depletion region generated by the p-n junction may propagate differently inside the n-well region with respect to a more symmetrical structure, thereby leading to a modification of the device behavior (e.g., C-V characteristic). The semiconductor variable capacitor 1100 also includes a trapezoid-shaped semiconductor region 114 disposed below the non-insulative region 112. The non-insulative region 106 is smaller than the control region 108, as illustrated, further contributing to the asymmetry of the semiconductor variable capacitor 1100. In certain aspects, the non-insulative region 112 may be trapezoid-shaped, while the semiconductor region 114 is rectangular, as illustrated in the semiconductor variable capacitor 1102. In this case, the non-insulative region 106 may have the same or a similar size as the control region 108, as illustrated.

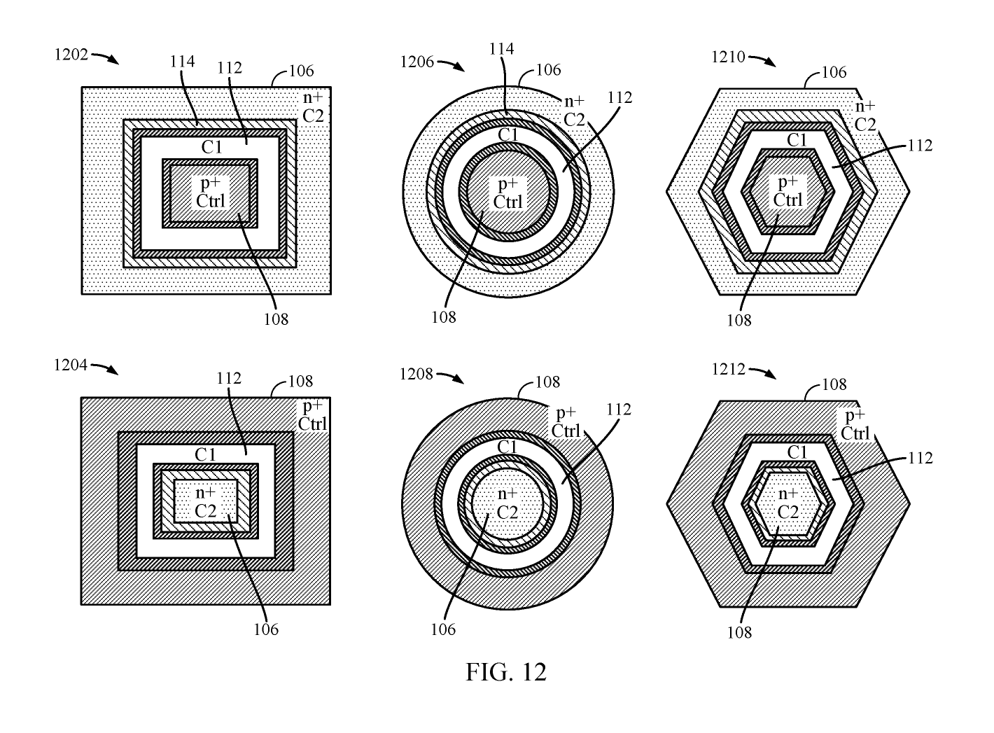

FIG. 12 illustrates top-down perspectives of example structures of semiconductor variable capacitors using different shaped polysilicon regions, in accordance with certain aspects of the present disclosure. For example, the TC device 1202 is implemented with a square (or rectangle)-shaped non-insulative region 112. In this case, the non-insulative region 106 and the control region 108 may also be implemented with a square (or rectangle) shape. In certain aspects, the non-insulative region 106 may be disposed at an outer region of the TC device, and the control region 108 may be disposed at an inner region of the TC device, as illustrated with TC 1202, or vice versa, as illustrated with TC 1204.

Certain aspects of the present disclosure provide a TC device that is implemented with a round-shaped (e.g., circular or oval) non-insulative region 112, as illustrated with TC device 1206 or TC device 1208. In this case, the non-insulative region 106 and the control region 108 may also be implemented with a round shape. Certain aspects of the present disclosure provide a TC device having a non-insulative region 112 shaped as a polygon with greater than four sides, as illustrated with TC device 1210 or TC device 1212. In this case, the non-insulative region 106 and the control region 108 may also be shaped as a polygon with greater than four sides.

While examples provided herein have illustrated a TC device to facilitate understanding, the techniques provided herein may be implemented with any variable capacitor having at least two terminals. For example, the semiconductor variable capacitor 302 of FIG. 3B may be implemented using a variable capacitor having two capacitor terminals (e.g., without a control (CTRL) terminal).

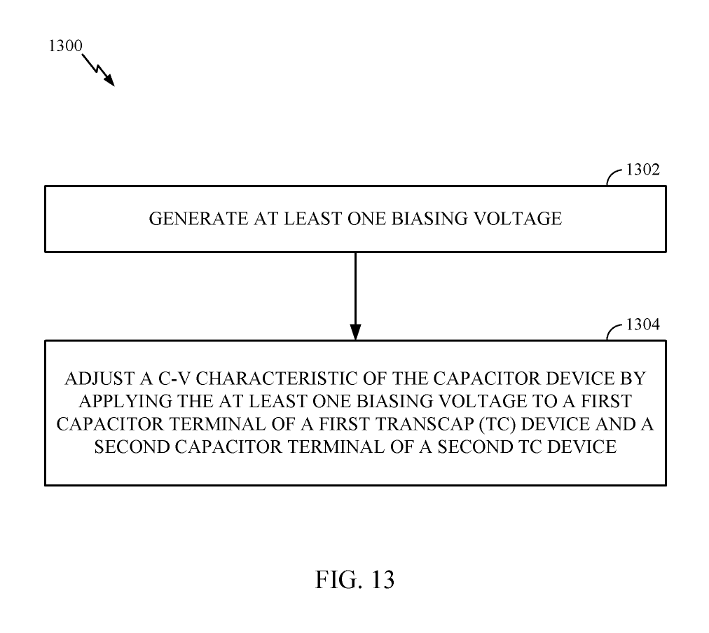

FIG. 13 is a flow diagram of example operations 1300 for adjusting a C-V characteristic of a capacitor device, in accordance with certain aspects of the present disclosure. The operations 1300 may be performed, for example, by a controller.

Operations 1300 may begin at block 1302 by generating at least one biasing voltage, and at block 1304, adjusting a C-V characteristic of the capacitor device by applying the at least one biasing voltage to a first capacitor terminal of a first TC device and a second capacitor terminal of a second TC device. In certain aspects, a decoupling capacitor may be coupled to each of the first capacitor terminals of the first TC device and the second capacitor terminal of the second TC device.

In certain aspects, the first TC device comprises a first differential TC device implemented with a third TC device and a fourth TC device, wherein a second capacitor terminal of the third TC device is coupled to a first capacitor terminal of the fourth TC device. Similarly, the second TC device may be a second differential TC device implemented with a fifth TC device and a sixth TC device, wherein a second capacitor terminal of the fifth TC device is coupled to a first capacitor terminal of the sixth TC device. In this case, the operations 1300 also include applying a first biasing voltage node to the second capacitor terminal of the third TC device and applying a second biasing voltage to a second capacitor terminal of the fifth TC device. In certain aspects, the first and second biasing voltages may be different voltages.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A capacitor device comprising:
a first variable capacitor and a second variable capacitor, each comprising a first terminal and a second terminal, wherein:
the second terminal of the second variable capacitor is coupled to the first terminal of the first variable capacitor; and
the first terminal of the first variable capacitor is coupled to at least one biasing voltage node; and
a decoupling capacitor coupled to the first terminal of the first variable capacitor.

2. The capacitor device of claim 1, wherein:
the first variable capacitor comprises a first differential variable capacitor, the first differential variable capacitor comprising a third variable capacitor and a fourth variable capacitor, wherein a second terminal of the third variable capacitor is coupled to a first terminal of the fourth variable capacitor; and
the second variable capacitor comprises a second differential variable capacitor, the second differential variable capacitor comprising a fifth variable capacitor and a sixth variable capacitor, wherein a second terminal of the fifth variable capacitor is coupled to a first terminal of the sixth variable capacitor.

3. The capacitor device of claim 2, wherein:
the second terminal of the third variable capacitor is coupled to the at least one biasing voltage node; and
the second terminal of the fifth variable capacitor is coupled to the at least one biasing voltage node.

4. The capacitor device of claim 3, wherein:
the at least one biasing voltage node comprises a first biasing voltage node and a second biasing voltage node;
the second terminal of the third variable capacitor is coupled to the first biasing voltage node; and
the second terminal of the fifth variable capacitor is coupled to the second biasing voltage node.

5. The capacitor device of claim 1, wherein the second terminal of the second variable capacitor is coupled to the at least one biasing voltage node.

6. The capacitor device of claim 5, wherein:
the at least one biasing voltage node comprises a first biasing voltage node and a second biasing voltage node;
the first terminal of the first variable capacitor is coupled to the first biasing voltage node; and
the second terminal of the second variable capacitor is coupled to the second biasing voltage node.

7. The capacitor device of claim 1, further comprising a decoupling capacitor coupled to the second terminal of the second variable capacitor.

8. The capacitor device of claim 1, further comprising a non-insulative region, wherein:
at least one of the first terminal or the second terminal of the first variable capacitor is coupled to the non-insulative region; and
the non-insulative region has a shape other than a quadrilateral with four right angles.

9. The capacitor device of claim 1, wherein each of the first variable capacitor and the second variable capacitor comprises a transcap (TC) device having a control terminal, the control terminal configured such that a capacitance between the first and second terminals of respective first and second variable capacitors is adjusted by varying a control voltage applied to the control terminal.

10. A capacitor device comprising:
a first variable capacitor and a second variable capacitor, each comprising a first terminal and a second terminal, wherein:
the first and second terminals of the first variable capacitor are coupled to the first and second terminals of the second variable capacitor, respectively; and
the first terminal of the first variable capacitor and the second variable capacitor are coupled to a first biasing voltage node.

11. The capacitor device of claim 10, further comprising a decoupling capacitor coupled to the first terminals of the first variable capacitor and the second variable capacitor.

12. The capacitor device of claim 10, further comprising another decoupling capacitor coupled to the second terminals of the first variable capacitor and the second variable capacitor, wherein the second terminals of the first variable capacitor and the second variable capacitor are coupled to a second biasing voltage node.

13. The capacitor device of claim 12, wherein the first biasing voltage node and the second biasing voltage node are different nodes.

14. The capacitor device of claim 10, wherein:
the first variable capacitor comprises a first differential variable capacitor, the first differential variable capacitor comprising a third variable capacitor and a fourth variable capacitor;
a second terminal of the third variable capacitor is coupled to a first terminal of the fourth variable capacitor;
the second variable capacitor comprises a second differential variable capacitor, the second differential variable capacitor comprising a fifth variable capacitor and a sixth variable capacitor; and
a second terminal of the fifth variable capacitor is coupled to a first terminal of the sixth variable capacitor.

15. The capacitor device of claim 10, wherein:
the second terminal of the third variable capacitor is coupled to a second biasing voltage node; and
the second terminal of the fifth variable capacitor is coupled to a third biasing voltage node.

16. The capacitor device of claim 15, wherein the second biasing voltage node and the third biasing voltage node are different nodes.

17. A capacitor device comprising:
a first transcap (TC) device and a second TC device, each comprising a first capacitor (C1) terminal, a second capacitor (C2) terminal, and a control terminal, wherein:
the control terminal is configured such that a capacitance between the C1 terminal and the C2 terminal is adjusted by varying a control voltage applied to the control terminal;
the C2 terminal of the first TC device is coupled to the C2 terminal of the second TC device;
at least one of the first TC device or the second TC device comprises a non-insulative region coupled to at least one of the C1 terminal, the C2 terminal, or the control terminal, of the at least one of the first TC device or the second TC device; and
the non-insulative region has a shape other than a quadrilateral with four right angles.

18. The capacitor device of claim 17, wherein the first TC device comprises another non-insulative region coupled to the control terminal or the C2 terminal of the first TC device, wherein the non-insulative region is coupled to the C1 terminal of the first TC device and is shaped as a trapezoid, and wherein the other non-insulative region is shaped as a polygon with four sides.

19. The capacitor device of claim 17, wherein the first TC device comprises another non-insulative region coupled to the control terminal or the C2 terminal of the first TC device, and wherein the non-insulative region is coupled to the C1 terminal of the first TC device, is round and, is formed around a perimeter of the other non-insulative region with respect to a perspective perpendicular to a top surface of the non-insulative region.

20. The capacitor device of claim 17, wherein:
the first TC device comprises another non-insulative region coupled to the control terminal or the C2 terminal of the first TC device; and
the non-insulative region is coupled to the C1 terminal of the first TC device, is shaped as a polygon with four sides, and is formed around a perimeter of the other non-insulative region with respect to a perspective perpendicular to a top surface of the non-insulative region.

21. The capacitor device of claim 17, wherein:
the first TC device comprises another non-insulative region coupled to the control terminal or the C2 terminal of the first TC device; and
the non-insulative region is coupled to the C1 terminal of the first TC device, is shaped as a polygon with greater than four sides, and is formed around a perimeter of the other non-insulative region with respect to a perspective perpendicular to a top surface of the non-insulative region.

22. The capacitor device of claim 17, wherein at least one of the C2 terminal or the C1 terminal of the first TC device is coupled to a first biasing voltage node.

23. The capacitor device of claim 17, wherein:
the C1 terminal, the C2 terminal, and the control terminal of the first TC device are connected to the C1 terminal, the C2 terminal, and the control terminal of the second TC device, respectively; and
the first TC device and the second TC device are implemented using different process parameters.

24. The capacitor device of claim 23, wherein:
the second TC device comprises another non-insulative region coupled to the control terminal or the C2 terminal of the second TC device; and
the non-insulative region is coupled to the C1 terminal of the first TC device and has a different length than the other non-insulative region.

25. The capacitor device of claim 17, wherein the non-insulative region is round.

26. The capacitor device of claim 17, wherein the non-insulative region is shaped as a triangle, a polygon with greater than four sides, or a trapezoid.

27. A capacitor device comprising:
a first transcap (TC) device and a second TC device, each comprising a first capacitor terminal, a second capacitor terminal, and a control terminal, wherein:
the control terminal is configured such that a capacitance between the first capacitor terminal and the second capacitor terminal is adjusted by varying a control voltage applied to the control terminal;
the first capacitor terminal of the first TC device is coupled to at least one biasing voltage node; and
the second capacitor terminal of the second TC device is coupled to the at least one biasing voltage node; and
a decoupling capacitor coupled to the first capacitor terminal of the first TC device.

28. The capacitor device of claim 27, further comprising another decoupling capacitor coupled to the second capacitor terminal of the second TC device.

29. The capacitor device of claim 27, wherein:
the first TC device comprises a first differential TC device, the first differential TC device comprising a third TC device and a fourth TC device;
a second capacitor terminal of the third TC device is coupled to a first capacitor terminal of the fourth TC device;
the second TC device comprises a second differential TC device, the second differential TC device comprising a fifth TC device and a sixth TC device; and
a second capacitor terminal of the fifth TC device is coupled to a first capacitor terminal of the sixth TC device.

30. The capacitor device of claim 27, wherein:
the second capacitor terminal of the third TC device is coupled to a first biasing voltage node; and
the second capacitor terminal of the fifth TC device is coupled to a second biasing voltage node.
